(19) United States
(12) Patent Application Publication
(10) Pub. No.: US 2014/0334108 A1
(43) Pub. Date: Nov. 13, 2014

(54) SEMICONDUCTOR PACKAGE MODULE HAVING SELF-ASSEMBLED INSULATION THIN FILM AND METHOD OF MANUFACTURING THE SEMICONDUCTOR PACKAGE MODULE

(71) Applicant: SAMSUNG ELECTRONICS CO., LTD., Suwon-Si (KR)

(72) Inventors: Jin-San JUNG, Asan-si (KR); Joo-Han LEE, Asan-si (KR); Jung-Chan CHO, Cheonan-si (KR); Hyun-Seok CHOI, Asan-si (KR)

(21) Appl. No.: 14/340,242

(22) Filed: Jul. 24, 2014

Related U.S. Application Data
(62) Division of application No. 13/017,452, filed on Jan. 31, 2011.

(30) Foreign Application Priority Data
Feb. 9, 2010 (KR) 10-2010-0012031

(51) Int. Cl. H05K 3/10; H05K 1/03; H05K 1/11

(52) U.S. Cl. CPC H05K 3/10; H05K 1/112; H05K 1/0353
USPC 361/728; 29/25.01

(57) ABSTRACT

A semiconductor package module including a self-assembled organic molecule layer and a method of manufacturing the semiconductor package module is provided. The semiconductor package module may include a module printed circuit board (PCB) having a plurality of metal line patterns and a plurality of mounting pads formed thereon. The semiconductor package may further include an insulation thin film self-assembled on at least one metal line pattern selected from among the plurality of metal line patterns. In order to manufacture the semiconductor package module, the insulation thin film is formed in a manner that the plurality of metal line patterns are formed on the module PCB wherein a plurality of via holes are formed, and then an organic compound is self-assembled on a surface of at least one metal line pattern selected from the plurality of metal line patterns.

### CROSS-REFERENCE TO RELATED APPLICATIONS

This application is a divisional application of U.S. application Ser. No. 13/017,452, filed on Jan. 31, 2011 and claims priority under 35 U.S.C. §119 to Korean Patent Application No. 10-2010-0012031, filed on Feb. 9, 2010, in the Korean Intellectual Property Office (KIPO), the disclosure of each of which is incorporated herein by reference.

### BACKGROUND

1. Field

Example embodiments relate to a semiconductor package module and a method of manufacturing the same, and more particularly, to a semiconductor package module having a printed circuit board (PCB) including metal lines and a method of manufacturing the semiconductor package module.

2. Background

Various kinds of electronic products have become miniaturized and highly-functional. Accordingly, there is a demand for highly integrated and high speed drives for electronic devices that are used in the electronic products. In the semiconductor industry, packing technologies are being developed to satisfy demands for compactness and mounting reliability. In the conventional art, semiconductor packages, which are a core device of the electronic products, are highly integrated and distances between metal lines in the semiconductor package module are relatively small. Thus, such devices are prone to short circuiting between the metal lines in the semiconductor package module.

### SUMMARY

Example embodiments provide a semiconductor package module having an improved reliability by preventing an undesired short between a plurality of adjacent lines or reducing the occurrence of an undesired short between a plurality of adjacent lines.

Example embodiments also provide a method of manufacturing a semiconductor package module whereby a minute and complicated wiring structure can be realized via a simplified and practical process in a short period of time, and an undesired short between a plurality of adjacent lines can be prevented or undesired shorts between a plurality of adjacent lines can be reduced.

In accordance with example embodiments, a semiconductor package module may include a module printed circuit board (PCB) having a plurality of metal line patterns and a plurality of mounting pads thereon and an insulation thin film self-assembled on at least one metal line pattern from among the plurality of metal line patterns.

In accordance with example embodiments, a method of manufacturing a semiconductor package module may include forming a plurality of metal line patterns, a plurality of mounting pads, and a plurality of tab terminals on a module printed circuit board (PCB) in which a plurality of via holes are formed, and forming an insulation thin film by self-assembling an organic compound on a surface of at least one metal line pattern from the plurality of metal line patterns.

In accordance with example embodiments, there is provided a semiconductor package module including a module printed circuit board (PCB) having a plurality of metal line patterns and a plurality of mounting pads formed thereon, and an insulation thin film self-assembled on at least one metal line pattern selected from among the plurality of metal line patterns.

The insulation thin film may be formed of a single molecule layer including organic molecules having an anchoring group self-assembled on surfaces of the at least one metal line pattern. The anchoring group may include a thiol derivative. The insulation thin film may include a molecular structure of Equation 1 below

—S—(CH₂)ₙ—X [Equation 1]

where n is an integer ranging from 1 to 20, and X indicates —CH₃, —COOH, —OH, —SH, or NH₂.

The insulation thin film may be formed of a plurality of organic molecule layers including a first organic molecule layer self-assembled on surfaces of the plurality of metal line patterns, and a second organic molecule layer that is hydrogen-bonded with the first organic molecule layer.

A plurality of via holes penetrating the module PCB may be formed in the module PCB, the plurality of metal line patterns may include first metal line patterns penetrating the plurality of via holes and extending from internal side-walls of the plurality of via holes to an external surface of the module PCB, and the insulation thin film may be self-assembled on surfaces of the first metal line patterns. Also, the insulation thin film may cover the surfaces of the first metal line patterns so as to prevent the first metal line patterns from being exposed to the outside of the module PCB.

In accordance with example embodiments, there is provided a semiconductor package module including a module printed circuit board (PCB) wherein a via hole, a metal line pattern penetrating the via hole, and a mounting pad neighbouring the metal line pattern around the via hole are formed, a semiconductor chip package mounted on the mounting pad on the module PCB, and an insulation thin film comprising a plurality of organic molecules comprising a thiol derivative self-assembled on the metal line pattern.

The via hole may have an empty space via which the insulation thin film is exposed.

In accordance with example embodiments, there is provided a method of manufacturing a semiconductor package module, the method including the operations of forming a plurality of metal line patterns, a plurality of mounting pads, and a plurality of tab terminals on a module printed circuit board (PCB) in which a plurality of via holes are formed, and forming an insulation thin film by self-assembling an organic compound on a surface of at least one metal line pattern selected from the plurality of metal line patterns.

The plurality of metal line patterns may include a copper line layer penetrating a via hole selected from the plurality of via holes and extending from an internal side-wall of the via hole to an external surface of the module PCB, and the operation of forming the insulation thin film may include the operation of self-assembling an organic compound on an exposed surface of the copper line layer.

The operation of forming the insulation thin film may include the operations of forming a mask pattern on the plurality of mounting pads and the plurality of tab terminals so as to expose at least one metal line pattern selected from among the plurality of metal line patterns, and self-assembling the organic compound on a surface of the at least one metal line pattern exposed by using the mask pattern.

The operation of forming the insulation thin film may include the operation of dipping the module PCB having the mask pattern formed thereon in a solvent where an organic compound comprising a thiol derivative is dissolved therein.

The organic compound may be denoted by Equation 2 below

HS—(CH₂)ₙ—X [Equation 2]

where n is an integer ranging from 1 to 20, and X indicates —CH₃, —COOH, —OH, —SH, or NH₂.

The operation of forming the insulation thin film may be performed under an atmosphere without water and oxygen.

The operation of forming the insulation thin film may include the operations of forming a first organic molecule layer by self-assembling a first organic compound on the surface of the at least one metal line pattern, and forming a second organic molecule layer by bonding a second organic compound with the first organic molecule layer.

The first organic molecule layer and the second organic molecule layer may be bonded to each other via hydrogen-bonding between —NH₂ groups. Also, the first organic molecule layer and the second organic molecule layer may be bonded to each other via hydrogen-bonding between —COOH groups.

The operation of forming the second organic molecule layer may be performed in-situ with the operation of forming the first organic molecule layer.

### BRIEF DESCRIPTION OF THE DRAWINGS

Example embodiments will be more clearly understood from the following detailed description taken in conjunction with the accompanying drawings in which:

FIG. 1 is a partial perspective view of a structure of a semiconductor package module according to example embodiments;

FIG. 2A is a plan view of the semiconductor package module of FIG. 1;

FIG. 2B is a plan view of a semiconductor package module having a mask pattern formed therein;

FIG. 3 is a partial cross-sectional view for describing parts of a semiconductor package module according to example embodiments;

FIG. 4 is a diagram of a structure of an insulation thin film that is self-assembled on a surface of a via hole metal line pattern in the semiconductor package module of FIG. 3;

FIG. 5 is a partial cross-sectional view for describing parts of a semiconductor package module according to example embodiments;

FIG. 6 is a diagram of a structure of the insulation thin film that is self-assembled on a surface of a via hole metal line pattern in the semiconductor package module of FIG. 5;

FIG. 7 is a flowchart of a method of manufacturing a semiconductor package module according to example embodiments;

FIG. 8 is a diagram of a semiconductor package module according to example embodiments;

FIG. 9 is a diagram of an electronic system including a semiconductor package module according to example embodiments; and

FIG. 10 is a diagram of a memory card including a semiconductor package module according to example embodiments.

### DETAILED DESCRIPTION OF THE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Hereinafter, example embodiments will be described in detail with reference to the attached drawings. However, it will be understood by those of ordinary skill in the art that various changes in form and details may be made therein without departing from the spirit and scope of example embodiments as defined by the appended claims. Example embodiments should be considered in a descriptive sense only and not for purposes of limitation. Therefore, the scope of the example embodiments is defined not by the detailed description but by the appended claims, and all differences within the scope will be construed as being included in example embodiments. Like reference numerals in the drawings denote like elements, and elements and regions in the drawings are schematically drawn. Thus, example embodiments are not limited to relative sizes or gaps drawn in the drawings.

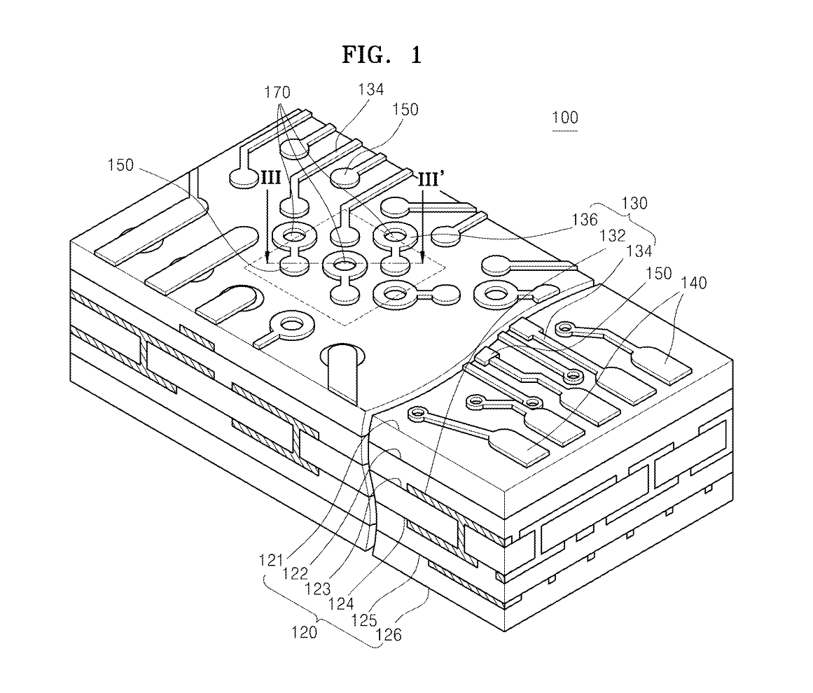

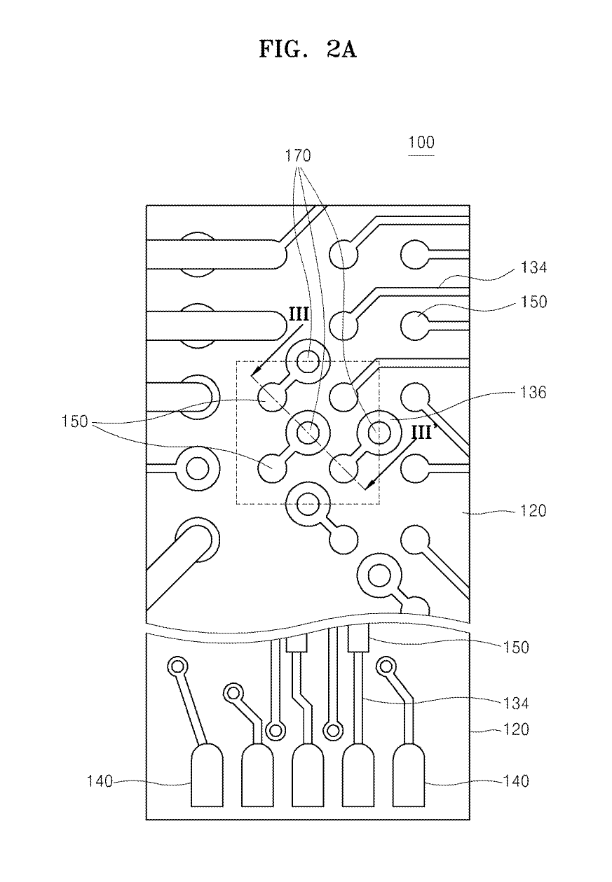

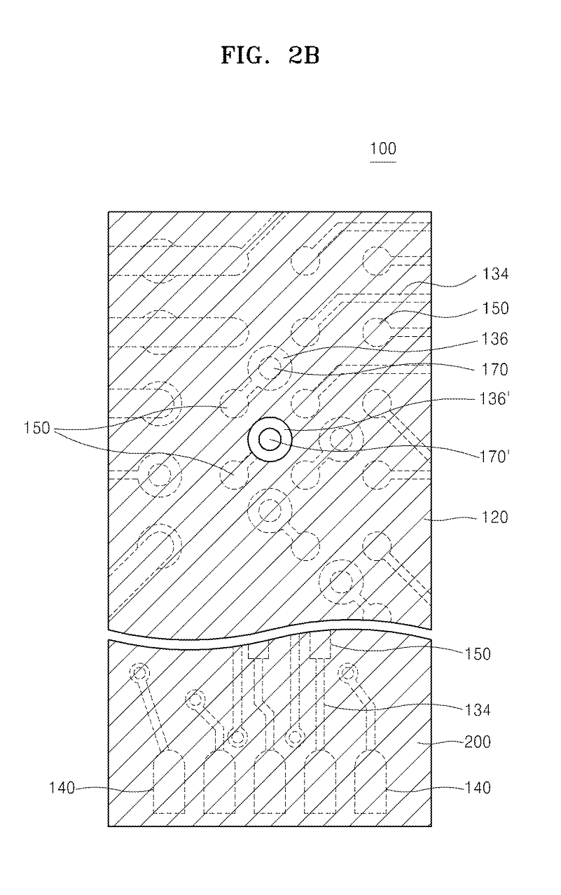

FIG. 1 is a partial perspective view of a structure of a semiconductor package module 100 according to example embodiments. FIG. 2A is a plan view of the semiconductor package module 100 of FIG. 1.

Referring to FIGS. 1 and 2A, the semiconductor package module 100 may be formed of a multi-layered substrate having a plural layer structure. The semiconductor package module 100 may include a module printed circuit board (module PCB) 120 which may have a plurality of circuit line layers 121 through 126, and a plurality of metal line patterns 130 that may be formed on the plurality of circuit line layers 121 through 126. The plurality of metal line patterns 130 may include a plurality of internal metal line patterns 132, a plurality of external metal line patterns 134, and a plurality of via hole metal line patterns 136.

A plurality of tab terminals 140 may be formed on an external surface of the semiconductor package module 100. The plurality of tab terminals 140 may be formed on an edge portion on the external surface of the module PCB 120. The plurality of tab terminals 140 may be provided for electrical connection with an external source, and may be connected to the plurality of internal metal line patterns 132 and the plurality of external metal line patterns 134.

Also, a plurality of mounting pads 150 may be formed on the external surface of the semiconductor package module 100. The plurality of mounting pads 150 may be electrically connected to parts of the plurality of metal line patterns 130. The plurality of mounting pads 150 may be provided for electrical connection between the module PCB 120 and a semiconductor chip package (not shown) that may be mounted on the module PCB 120.

A plurality of via holes 170 penetrating the module PCB 120 may be formed in the semiconductor package module 100. Each of the plurality of via hole metal line patterns 136 may extend from an internal side-wall of each of the plurality of via holes 170 to an external surface of the module PCB.

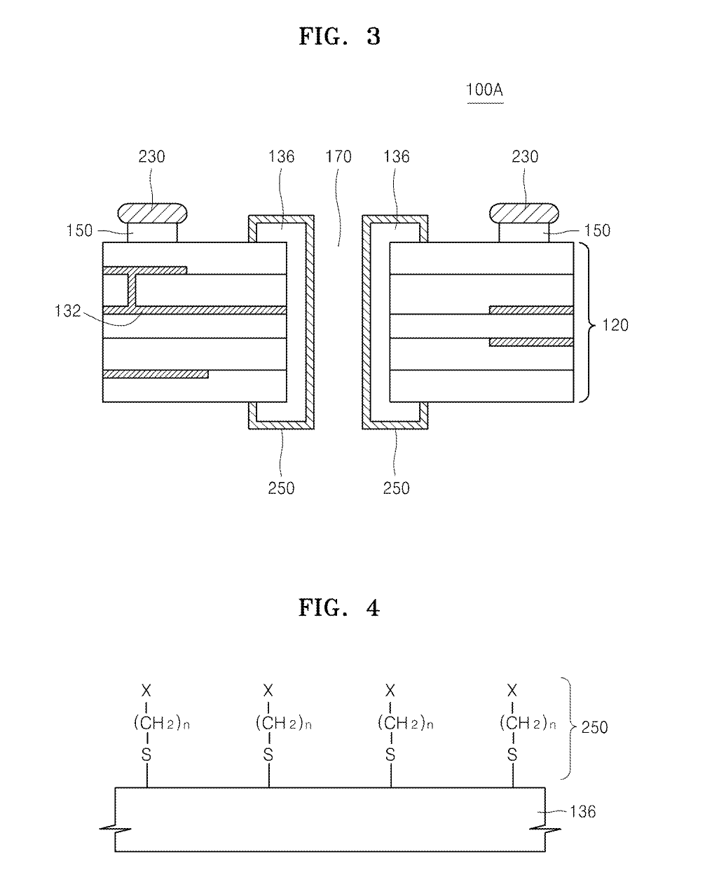

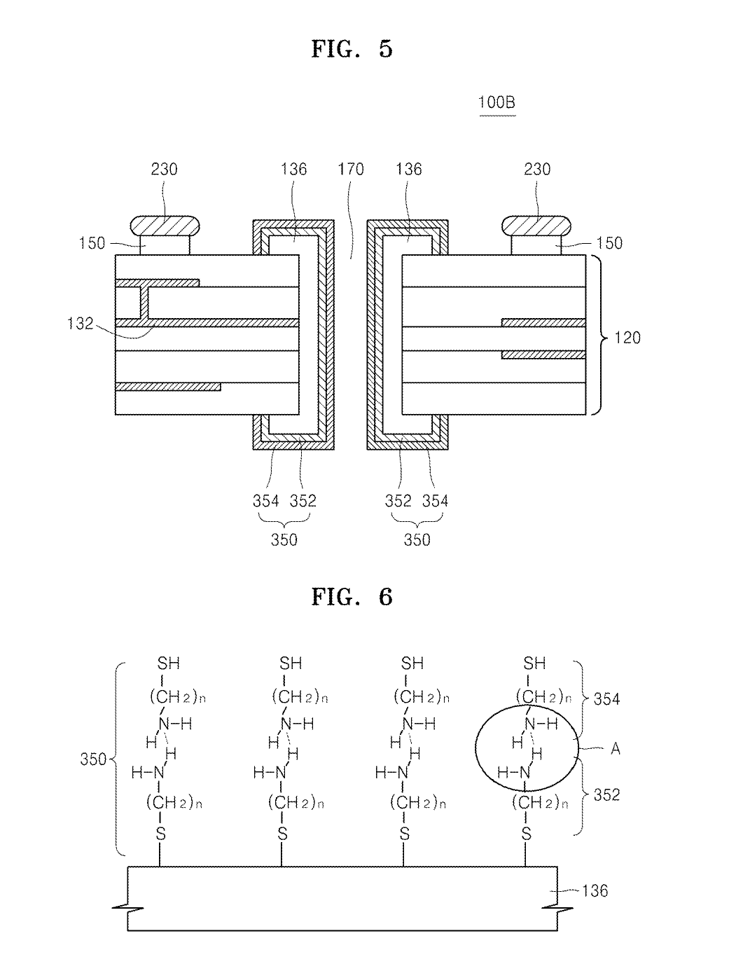

Each of the plurality of via hole metal line patterns 136 may be covered with an insulation thin film (refer to reference numerals 250 of FIG. 3 and 350 of FIG. 5) that is self-assembled on a surface of each via hole metal line pattern 136. A detailed description for the insulation thin films 250 and 350 will be provided later with reference to FIGS. 3 through 6.

FIG. 3 is a partial cross-sectional view for describing parts of a semiconductor package module 100A according to example embodiments. The diagram of FIG. 3 may correspond to a magnified cross-sectional view that is taken along a line III-III′ of FIGS. 1 and 2A. In FIG. 3, like reference numerals in FIGS. 1 and 2A denote like elements, and thus, detailed descriptions thereof are omitted here.

Referring to FIG. 3, a side-wall of the via hole 170 penetrating the module PCB 120 may be covered with the via hole metal line pattern 136. As illustrated in FIG. 3, the via hole metal line pattern 136 may extend from the internal side-wall of the via hole 170 to the external surface of the module PCB 120. The via hole metal line pattern 136 may be formed of a plated copper layer.

In example embodiments a distance between the via hole metal line pattern 136 and a neighbouring mounting pad 150 on the module PCB 120 may be relatively small. When the distance between the via hole metal line pattern 136 and the neighbouring mounting pad 150 on the module PCB 120 is relatively small, and a surface mounting technology (SMT) process is performed to print a solder paste 230 on the mounting pad 150 formed on the module PCB 120 so as to mount the semiconductor chip package (not shown) on the module PCB 120, a short may occur between the via hole metal line pattern 136 and the neighbouring mounting pad 150 if the solder paste 230 is not printed on an exact position on the mounting pad 150. For example, the surface mounting technology (SMT), if not precisely controlled, may form the solder paste 230 on both the via hole metal line pattern 136 and the neighbouring mounting pad 150 thus causing a short between the via hole metal line pattern 136 and the neighbouring mounting pad 150.

In order to prevent the short from occurring between the via hole metal line pattern 136 and the mounting pad 150, or reduce an occurrence of a short between the via hole metal line pattern 136 and the mounting pad 150, example embodiments include the insulation thin film 250 on the surface of the via hole metal line pattern 136. In example embodiments, the insulation thin film 250 may be self-assembled on the surface of the via hole metal line pattern 136.

In example embodiments, the insulation thin film 250 may be formed of a molecule layer that includes a thiol derivative. In example embodiments, the thiol derivative may be selectively combined on the surface of the via hole metal line pattern 136 according to a self-assembling method using the thiol derivative as an anchoring group. In example embodiments the thiol derivative may include a thiol group (thiol, —SH) or a dithiol group (dithiol, —S—S—) either of which may form a stable self-assembled monolayer (SAM) on a metal material, for example, a copper (Cu) material, a gold (Au) material, a platinum (Pt) material, a argentums (Ag) material, and a palladium (Pd) material.

The insulation thin film 250 may be formed of a single molecule layer including organic molecules that are self-assembled on the surface of the via hole metal line pattern 136. For example, the insulation thin film 250 may include a self-assembled molecular structure of Equation 1 below.

—S—(CH₂)ₙ—X [Equation 1]

where n is an integer between 1 through 20, and X indicates —CH₃, —COOH, —OH, —SH, or NH₂.

FIG. 4 is a diagram of a structure of the insulation thin film 250 that may be self-assembled on the surface of the via hole metal line pattern 136 in the semiconductor package module 100A of FIG. 3. FIG. 4 corresponds to a case in which the insulation thin film 250 is formed as a single molecule layer including molecules denoted by Equation 1.

In order to adjust a thickness of the insulation thin film 250 illustrated in FIGS. 3 and 4, a length of a carbon chain of a hydrocarbon group may be adjusted by appropriately selecting a value of n in —(CH₂)ₙ—.

FIG. 5 is a partial cross-sectional view for describing parts of a semiconductor package module 100B according to example embodiments. The diagram of FIG. 5 may correspond to a magnified cross-sectional view that is taken along a line III-III′ of FIGS. 1 and 2A. In FIG. 5, like reference numerals in FIGS. 1 and 2A denote like elements, and thus, detailed descriptions thereof are omitted here.

Referring to FIG. 5, a side-wall of the via hole 170 penetrating the module PCB 120 may be covered with the via hole metal line pattern 136. An insulation thin film 350 formed of a plurality of organic molecule layers may be formed on a surface of the via hole metal line pattern 136. The plurality of organic molecule layers forming the insulation thin film 350 may include a first organic molecule layer 352 self-assembled on the surface of the via hole metal line pattern 136, and a second organic molecule layer 354 that is hydrogen-bonded with the first organic molecule layer 352.

The first organic molecule layer 352 may be formed in a manner that a compound including a thiol derivative is selectively combined on the surface of the via hole metal line pattern 136 according to a self-assembling method using the thiol derivative as an anchoring group.

FIG. 6 is a diagram of a structure of the insulation thin film 350 that may be self-assembled on the surface of the via hole metal line pattern 136 in the semiconductor package module 100B of FIG. 5.

The insulation thin film 350 of FIG. 6 has a double-layer structure including an organic compound that has a structure of HS—(CH₂)ₙ—NH₂ (where n is an integer ranging from 1 to 20) and that includes the first organic molecule layer 352 self-assembled on the surface of the via hole metal line pattern 136, and the second organic molecule layer 354. In the insulation thin film 350 of FIG. 6, the first organic molecule layer 352 and the second organic molecule layer 354 forming the insulation thin film 350 may be bonded to each other via hydrogen-bonding between —NH₂ groups, as illustrated in an area A.

Although FIG. 6 corresponds to a case in which the first organic molecule layer 352 and the second organic molecule layer 354 are bonded to each other via hydrogen-bonding between —NH₂ groups, example embodiments are not limited to the case of FIG. 6. For example, the insulation thin film 350 may be formed using a compound having a structure of HS—(CH₂)ₙ—COOH (where n is an integer between 1 through 20), and the first organic molecule layer 352 and the second organic molecule layer 354 may be bonded to each other via hydrogen-bonding between —COOH groups.

In order to adjust a thickness of the insulation thin films 350 illustrated in FIGS. 5 and 6, a length of a carbon chain of a hydrocarbon group may be adjusted by appropriately selecting a value of n in —(CH₂)ₙ—.

Forming the insulation thin film 250 or 350 on the surface of the via hole metal line pattern 136 formed through the via hole 170 in the module PCB 120 of the semiconductor package modules 100, 100A, and 100B according to example embodiments, may prevent a short from occurring between the via hole metal line pattern 136 and conductive patterns e.g., the mounting pads 150 that are adjacent to the via hole metal line pattern 136. In the alternative, the insulation thin film 250 or 350 may reduce the occurrence of a short from occurring between the via hole metal line pattern 136 and a conductive pattern e.g., the mounting pads 150 that are adjacent to the via hole metal line pattern 136.

Because the insulation thin films 250 or 350 may be formed on the surface of the via hole metal line pattern 136 formed by penetrating the via hole 170 in the module PCB 120 of the semiconductor package modules 100, 100A, and 100B according to example embodiments, a conventional process of filling the via hole 170 by using a plugging ink or a plugging paste may be omitted. That is, in the module PCB 120 of the semiconductor package modules 100, 100A, and 100B according to example embodiments, the via hole 170 may have an empty space in which the insulation thin film 250 or 350 is exposed. In example embodiments, a plurality of the via holes 170 having various diameters may be formed in the semiconductor package modules 100, 100A, and 100B.

In example embodiments, however, the plugging ink or the plugging paste may be filled in an internal space of the via hole 170 according to a general plugging process. In example embodiment, the plugging process may or may not be simultaneously performed on a plurality of via holes having diameters of different sizes.

Because the insulation thin film 250 or 350 is self-assembled on the surface of the via hole metal line pattern 136 in the semiconductor package modules 100, 100A, and 100B, the insulation thin film 250 or 350 may be uniformly self-assembled on an exposed surface of the via hole metal line pattern 136, regardless of a diameter of the via hole 170. Thus, in the semiconductor package module 100A according to example embodiments, although the plurality of the via holes 170 having diameters of different sizes are formed in the module PCB 120, it is possible to simultaneously form the insulation thin film 250 having a uniform thickness in each of the plurality of the via holes 170.

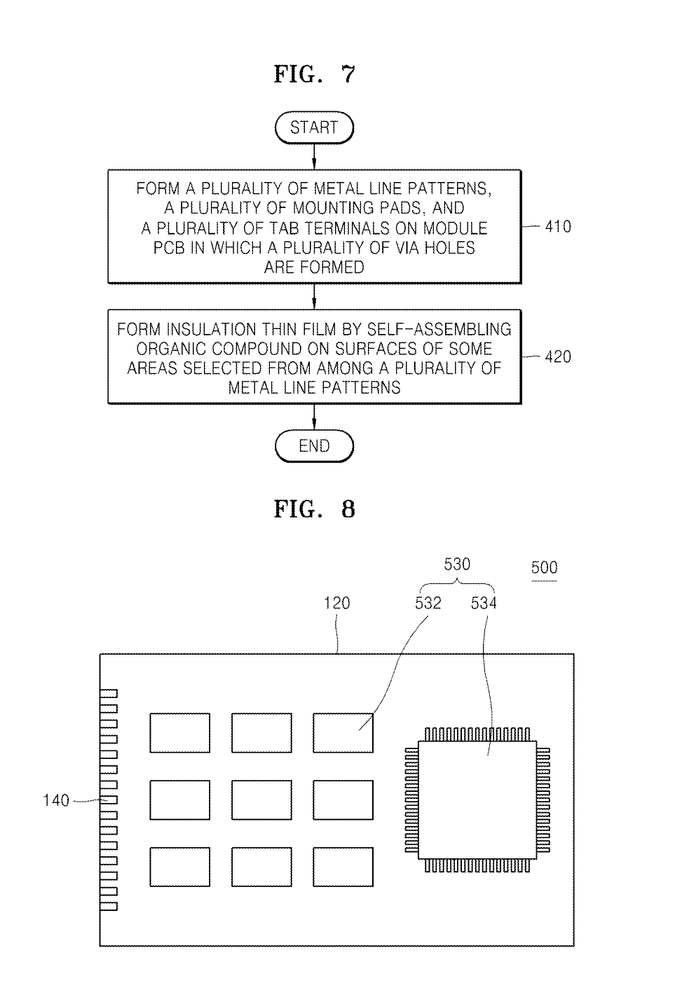

FIG. 7 is a flowchart of a method of manufacturing a semiconductor package module, according to example embodiments.

Referring to FIG. 7, various unit devices including the plurality of metal line patterns 130, the plurality of mounting pads 150, and the plurality of tab terminals 140 are formed on the module PCB 120 in which the plurality of via holes 170 are formed (process 410).

As described with reference to FIGS. 1 and 2A, the metal line patterns 130 may include the plurality of internal metal line patterns 132, the plurality of external metal line patterns 134, and the plurality of via hole metal line patterns 136. In example embodiments, the various unit devices may be formed on the module PCB 120 and the various unit devices may include various lines, resistors, active devices, and the like.

After that, an organic compound is self-assembled on surfaces of portions selected from the metal line patterns 130, so that an insulation thin film is formed (process 420).

The insulation thin film may include the insulation thin film 250 described with reference to FIGS. 3 and 4, or the insulation thin film 350 described with references to FIGS. 5 and 6.

The organic compound used in process 420 may be formed of an organic compound denoted by Equation 2.

HS—(CH₂)ₙ—X [Equation 2]

where n is an integer ranging from 1 to 20, and X indicates —CH₃, —COOH, —OH, —SH, or NH₂.

As illustrated in FIGS. 3 through 6, in order to selectively form the insulation thin film 250 or 350 only on the surface of the via hole metal line pattern 136, a mask pattern (not shown in FIGS. 3 through 6) may be used. After the metal line patterns 130 are formed according to process 410 of FIG. 7, the mask pattern may cover regions not requiring the insulation thin film 250 or 350 to be formed thereon, wherein the regions include some portions of the plurality of external metal line patterns 134 that are exposed to an external surface of the module PCB 120, the plurality of mounting pads 150, and the plurality of tab terminals 140. After that, the organic compound denoted by Equation 2 may be selectively self-assembled only on portions exposed by the mask pattern, so that the insulation thin film 250 or 350 may be formed on surfaces of the via hole metal line patterns 136.

FIG. 2B is a plan view of a semiconductor package module 100 having a mask pattern 200 formed thereon. In FIG. 2B the mask pattern 200 covers the tab terminals 140, the external metal line patterns 134, the mounting pads 150, and the external metal lines 134, thus, only a surface of the via hole metal line pattern 136′ is exposed by the mask pattern 200. Although FIG. 2B illustrates only a single via hole metal line pattern 136′ being exposed, example embodiments are not limited thereto as other metal line patterns, for example some or all of the via hole metal line patterns 136, may be exposed. As described above, the mask pattern 200 may be formed after the metal line patterns 130 are formed according to process 410 of FIG. 7. As shown in FIG. 2B, the mask pattern may cover regions not requiring the insulation thin film 250 or 350 to be formed thereon. The organic compound denoted by Equation 2 may be selectively self-assembled only on portions exposed by the mask pattern so that the insulation thin film 250 or 350 may be formed on surfaces of a via hole metal line patterns 136, for example, the via hole metal line pattern 136′.

In order to form the insulation thin film 250 or 350, the module PCB 120 including a mask pattern (not shown in FIGS. 3 through 6) for exposing the via hole metal line patterns 136 may be dipped for several minutes or hours, e.g., for 30 minutes or 48 hours, in an organic solvent where the organic compound denoted by Equation 2 is dissolved therein, and then a washing and a drying processes may be performed on the module PCB 120.

The mask pattern may be formed of a film for dry-film resist (DFR). Also, the mask pattern may be formed of a material having a characteristic of a hydrophobic surface on which the organic compound is not self-assembled.

The dipping process may be performed under an environment without water and oxygen. The organic solvent may include, for example, ethanol, chloroform (CHCl₃), and dimethylformamide (DMF).

In particular, as described with reference to FIGS. 5 and 6, in a case where the insulation thin film 350 is formed of a plurality of organic molecule layers including the first organic molecule layer 352 and the second organic molecule layer 354, a process in which the first organic molecule layer 352 is self-assembled on the surface of the via hole metal line pattern 136, and another process in which the second organic molecule layer 354 is hydrogen-bonded with the first organic molecule layer 352 may be performed in-situ.

Process 420 in the method of FIG. 7 may be performed after a photo-imageable solder resist (PSR) process is performed on a resultant that corresponds to the various unit devices including the plurality of metal line patterns 130, the plurality of mounting pads 150, and the plurality of tab terminals 140 and formed on the module PCB 120 in which the plurality of via holes 170 are formed. That is, a PSR pattern may be formed on the module PCB 120 so as to expose portions of the metal line patterns 130, the plurality of mounting pads 150, and the plurality of tab terminals 140, wherein the portions are required to have the insulation thin film 250 or 350 formed thereon, and then process 420 may be performed while parts such as the plurality of mounting pads 150 and the plurality of tab terminals 140 that are not required to have the insulation thin film 250 or 350 formed thereon are covered with a mask pattern (see FIG. 2B), so that the organic compound denoted by Equation 2 may be selectively self-assembled only in desired portions. After that, by removing the mask pattern, it is possible to obtain a resultant in which the insulation thin film 250 or 350 is selectively formed only in the desired portions including the plurality of via hole metal line patterns 136.

Although not illustrated in the drawings, by appropriately designing a shape of the PSR pattern and a shape of the mask pattern, it is possible to allow the insulation thin film 250 or 350 to be formed not only on surfaces of the plurality of via hole metal line patterns 136 but also formed on surfaces of selected portions of the plurality of external metal line patterns 134.

By forming the insulation thin film 250 or 350 on each of the portions of the plurality of external metal line patterns 134 and the plurality of via hole metal line patterns 136 on the module PCB 120, wherein the portions are exposed to the outside and require to be insulated from the outside, the insulation thin film 250 or 350 may substitute for a function of a conventional PSR pattern. Thus, according to example embodiments, it is possible to omit a PSR process in manufacture of a semiconductor package module.

As described above, although the semiconductor package modules 100, 100A, and 100B including the module PCB 120 having the insulation thin film 250 or 350 formed thereon have been described, example embodiments are not limited thereto. Thus, example embodiments may be applied to various types of semiconductor devices and semiconductor package modules including the semiconductor devices.

FIG. 8 is a diagram of a semiconductor package module 500 according to example embodiments.

Referring to FIG. 8, the semiconductor package module 500 according to example embodiments may include a semiconductor chip package 530 having various shapes mounted on the module PCB 120. For example, the semiconductor chip package 530 may include a first semiconductor chip package 532 of a ball grid array (BGA) type, and a second semiconductor chip package 534 of a quad flat package (QFP) type. The semiconductor package module 500 may be connected to an external electronic device via the plurality of tab terminals 140 corresponding to external-connection terminals that are arranged on a side portion of the module PCB 120.

Each of the first semiconductor chip package 532 and the second semiconductor chip package 534 may include the insulation thin film 250 or 350 that is described with reference to FIGS. 1 through 7.

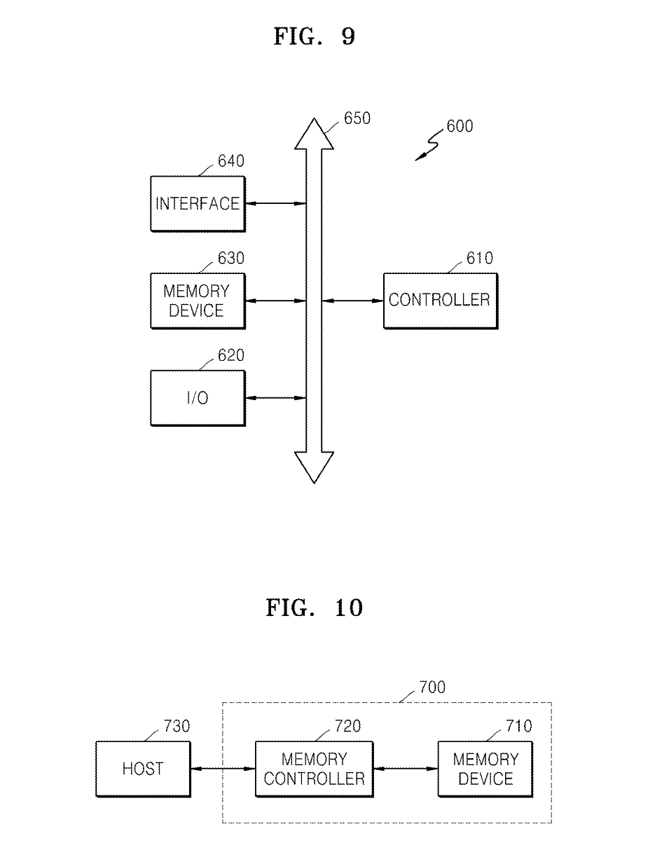

FIG. 9 is a diagram of an electronic system 600 including a semiconductor package module, according to example embodiments.

Referring to FIG. 9, the electronic system 600 may include a controller 610, an input/output (I/O) device 620, and a memory device 630. The controller 610, the I/O device 620, and the memory device 630 may be connected to each other via a bus 650.

The controller 610 may include at least one selected from the group consisting of at least one microprocessor, a digital signal processor (DSP), a microcontroller, and a logic device configured to perform similar functions to the at least one microprocessor, the DSP, and the microcontroller.

The controller 610 may include the semiconductor package module 100, 100A, 100B, or 500 including the insulation thin film 250 or 350 described with reference to FIGS. 1 through 7.

The I/O device 620 may include keypads, a keyboard, or a display device.

The memory device 630 may be a device configured to store data, and may store the data, or a command to be executed by using the controller 610. The memory device 630 may include the semiconductor package module 100, 100A, 100B, or 500 including the insulation thin film 250 or 350 described with reference to FIGS. 1 through 7.

The electronic system 600 may further include an interface 640 configured to transmit data to a communication network or receive data from the communication network. The interface 640 may be wireless or wired. For example, the interface 640 may include an antenna or a wire and wireless transceiver.

Although not illustrated in the drawings, the electronic system 600 may further include an application chipset, a camera image processor, an I/O device and the like.

The electronic system 600 may be embodied as a mobile system, a personal computer (PC), an industrial computer, or a logic system for performing various functions. For example, the mobile system may be configured as a personal digital assistant (PDA), a portable computer, a web tablet, a mobile phone, a wireless phone, a laptop computer, a memory card, a digital music system, an information transceiving system, or the like. In example embodiments the electronic system 600 may be a device capable of performing wireless communication, and the electronic system 600 may be used in a communication interface protocol including a third generation (3G) communication system, for example, as Code Division Multiple Access (CDMA), Global System for Mobile communication (GSM), North America Digital Cellular (NADC), Evolutionary-Time Division Multiple Access (E-TDMA), Wideband Code Division Multiple Access (WCDMA), CDMA2000, and the like.

FIG. 10 is a diagram of a memory card 700 including a semiconductor package module, according to example embodiments. Referring to FIG. 10, the memory card 700 may include a memory device 710 formed of a non-volatile memory device, and a memory controller 720. The memory device 710 may store data or read stored data. The memory device 710 may include the semiconductor package module 100, 100A, 100B, or 500 including the insulation thin film 250 or 350 described with reference to FIGS. 1 through 7.

The memory controller 720 may read stored data in response to read/write requests from a host 730, or may control the memory device 710 to store data. The semiconductor package module according to example embodiments includes the insulation thin film self-assembled on the surface of the via hole metal line pattern formed by penetrating the via hole in the module PCB. Thus, a short between the via hole metal line patterns and the conductive patterns adjacent to the via hole metal line patterns may not occur or the number of shorts between the via hole metal line patterns and the conductive patterns may be reduced.

Also, in the module PCB of the semiconductor package module according to example embodiments, although the plurality of the via holes having diameters of different sizes are formed in the module PCB, it is possible to simultaneously form the insulation thin film having a uniform thickness in each of the plurality of the via holes. In this regard, since a design of the module PCB is not limited by the sizes of the via holes, a design limitation may be decreased.

In addition, according to the method of manufacturing a semiconductor package module, according to example embodiments, by allowing the insulation thin film to be self-assembled only on surfaces of the metal line patterns exposed to the outside of the module PCB and surfaces of the via hole metal line patterns formed by penetrating the via holes, wherein the surfaces are required to be insulated from the outside, the plugging process and the PSR process may be omitted. Thus, according to example embodiments, a process time may be shortened and manufacturing costs may be reduced or minimized so that productivity may be increased.

While example embodiments have been particularly shown and described, it will be understood that various changes in form and details may be made therein without departing from the spirit and scope of the following claims.

1-5. (canceled)

6. A semiconductor package module comprising:
a module printed circuit board (PCB) having a plurality of metal line patterns and a plurality of mounting pads thereon;
an insulation thin film self-assembled on at least one metal line pattern from among the plurality of metal line patterns;
wherein the insulation thin film is a single molecule layer comprising organic molecules having an anchoring group self-assembled on surfaces of the at least one metal line pattern;
wherein the anchoring group includes a thiol derivative;
wherein the module PCB includes at least one via hole penetrating the module PCB,
the at least one metal line pattern includes a first metal line pattern penetrating the at least one via hole and extending from internal side-walls of the at least one via hole to an external surface of the module PCB, and
the insulation thin film is self-assembled on surfaces of the first metal line pattern.

7. The semiconductor package module of claim 6, wherein the insulation thin film covers the surfaces of the first metal line pattern and is configured to prevent the first metal line pattern from being exposed to the outside of the module PCB.

8. A semiconductor package module comprising:
the semiconductor package module of claim 6; and
a semiconductor chip package on the module printed circuit board (PCB), the semiconductor chip package being arranged on at least one mounting pad of the plurality of mounting pads, wherein
the module printed circuit board (PCB) includes a via hole,
the at least one metal line pattern penetrates the via hole, and
the insulation thin film includes a plurality of organic molecules comprising a thiol derivative self-assembled on the at least one metal line pattern.

9. The semiconductor package module of claim 8, wherein the via hole is an empty space in which the insulation thin film is exposed.

10. The semiconductor package module of claim 8, wherein the insulation thin film includes one of a single molecule layer and a double molecule layers comprising a plurality of organic molecules having a molecular structure of Equation 1 below
—S—(CH₂)ₙ—X [Equation 1]
where n is an integer ranging from 1 to 20, and X indicates one of —CH₃, —COOH, —OH, —SH, and NH₂.

11. A method of manufacturing a semiconductor package module, the method comprising:
forming a plurality of metal line patterns, a plurality of mounting pads, and a plurality of tab terminals on a module printed circuit board (PCB) in which a plurality of via holes are formed; and
forming an insulation thin film by self-assembling an organic compound on a surface of at least one metal line pattern from the plurality of metal line patterns.

12. The method of claim 11, wherein
forming the plurality of metal line patterns includes forming a copper line layer penetrating a via hole selected from the plurality of via holes and extending from an internal side-wall of the via hole to an external surface of the module PCB; and
forming the insulation thin film comprises self-assembling the organic compound on an exposed surface of the copper line layer.

13. The method of claim 11, wherein
forming the insulation thin film includes forming a mask pattern on the plurality of mounting pads and the plurality of tab terminals to expose at least one metal line pattern selected from among the plurality of metal line patterns, and
self-assembling the organic compound on a surface of the at least one metal line pattern exposed by the mask pattern.

14. The method of claim 13, wherein forming of the insulation thin film includes dipping the module PCB having the mask pattern formed thereon in a solvent where an organic compound comprising a thiol derivative is dissolved therein.

15. The method of claim 14, wherein the organic compound is denoted by Equation 2 below
HS—(CH₂)ₙ—X [Equation 2]
where n is an integer ranging from 1 to 20, and X indicates one of —CH₃, —COOH, —OH, —SH, and NH₂.

16. The method of claim 14, wherein forming the insulation thin film includes forming the insulation thin film in an environment without water and oxygen.

17. The method of claim 11, wherein forming the insulation thin film includes
forming a first organic molecule layer by self-assembling a first organic compound on the surface of the at least one metal line pattern, and
forming a second organic molecule layer by bonding a second organic compound with the first organic molecule layer.

18. The method of claim 17, wherein the first organic molecule layer and the second organic molecule layer are bonded to each other via hydrogen-bonding between —NH₂ groups.

19. The method of claim 17, wherein the first organic molecule layer and the second organic molecule layer are bonded to each other via hydrogen-bonding between —COOH groups.

20. The method of claim 17, wherein forming the second organic molecule layer includes forming the second organic molecule layer in-situ with forming of the first organic molecule layer.
